(19) United States
(12) Patent Application Publication
(10) Pub. No.: US 2010/0140683 A1
(43) Pub. Date: Jun. 10, 2010

(54) SILICON NITRIDE FILM AND NONVOLATILE SEMICONDUCTOR MEMORY DEVICE

(75) Inventors: Seiichi Miyazaki, Hiroshima-ken (JP); Masayuki Kohno, Hyogo-Ken (JP); Tatsuo Nishita, Hyogo-Ken (JP); Toshio Nakanishi, Hyogo-Ken (JP); Yoshihiro Hirota, Hyogo-Ken (JP)

Correspondence Address: SMITH, GAMBRELL & RUSSELL, 1130 CONNECTICUT AVENUE, N.W., SUITE 1130, WASHINGTON, DC, 20036, US

(73) Assignees: TOKYO ELECTRON LIMITED, Tokyo-To (JP); HIROSHIMA UNIVERSITY, Hiroshima-Ken (JP)

(21) Appl. No.: 12/532,681

(22) PCT Filed: Mar. 26, 2008
(86) PCT No.: PCT/JP2008/055679

§ 371 Date: Mar. 1, 2010

(30) Foreign Application Priority Data
Mar. 26, 2007 (JP) 2007-79852
Sep. 28, 2007 (JP) 2007-254273

(51) Int. Cl. H01L 29/792; C01B 21/068; H01L 21/318; H01L 21/316

(52) U.S. Cl. 257/324; 423/344; 438/792; 438/763; 257/314; 257/E21.293; 257/E21.278; 257/E29.309

(57) ABSTRACT

Provided is a silicon nitride film which has an excellent charge storage capacity and thus is useful as a charge storage layer of a semiconductor memory device. The silicon nitride film having substantially uniform trap density in the film thickness direction has high charge storage performance. The silicon nitride film is formed by plasma CVD by using a plasma processing apparatus (100), wherein microwaves are introduced into a chamber (1) by a plane antenna having a plurality of holes, plasma is generated by the microwaves while a source gas including nitrogen-containing compound and silicon-containing compound is introduced into the chamber (1), and the silicon nitride film is deposited on the surface of a processing object by the plasma.

### TECHNICAL FIELD

The present invention relates to a silicon nitride film which is useful as a charge storage layer of a nonvolatile semiconductor memory device, and also to a nonvolatile semiconductor memory device.

### BACKGROUND ART

Current nonvolatile semiconductor memory devices, as typified by electrically rewritable EEPROM (electrically erasable and programmable ROM), include those having a laminate structure, called SONOS (silicon-oxide-nitride-oxide-silicon) type or MONOS (metal-oxide-nitride-oxide-silicon) type. In these types of nonvolatile semiconductor memory devices, holding of information is performed with a silicon nitride film (nitride), sandwiched between silicon dioxide films (oxide), as a charge storage layer. In particular, in such a nonvolatile semiconductor memory device, by applying a voltage between a semiconductor substrate (silicon) and a control gate electrode (silicon or metal), electrons are injected into a silicon nitride film as a charge storage layer to store data, or electrons stored in the silicon nitride film are removed to erase data. Rewriting of data is thus performed.

As a technique concerning a charge storage layer of a nonvolatile semiconductor memory device, Japanese Patent Laid-Open Publication No. 5-145078 describes providing an intermediate transition layer, having a high Si content, between a silicon nitride film and a top oxide film in order to increase the trap density at the interface between the films.

With the recent higher integration of semiconductor devices, the device structures of nonvolatile semiconductor memory devices are becoming increasingly miniaturized. To miniaturize a nonvolatile semiconductor memory device, it is necessary to enhance the charge storage capacity of a silicon nitride film as a charge storage layer in the memory device, thereby enhancing the data storage capacity. The charge storage capacity of a silicon nitride film is related to the density of traps, which serve as a charge capture center, in the film. The use of a silicon nitride film having a high trap density as a charge storage layer is therefore considered effective as a means for enhancing the data storage capacity of a nonvolatile semiconductor memory device.

However, it has been impossible to determine the density of traps or its distribution in a silicon nitride film. Therefore, there are no clear guidelines as to what level of trap density or what trap density profile a silicon nitride film should have for its use as a storage layer of a semiconductor memory device. Further, it has been virtually impossible to control the density of traps or its distribution in a silicon nitride film in the course of the formation of the film. For example, because of the impossibility of direct control of the trap density of a silicon nitride film, the above-described transition layer is provided between a silicon nitride film and a top oxide film according to the technique of Japanese Patent Laid-Open Publication No. 5-145078.

### DISCLOSURE OF THE INVENTION

The present invention has been made in view of the above problems. It is therefore an object of the present invention to provide a silicon nitride film which has an excellent charge storage capacity and thus is useful as a charge storage layer of a semiconductor memory device.

According to a first aspect of the present invention, there is provided a silicon nitride film for use as a charge storage layer of a nonvolatile semiconductor memory device, wherein the surface density of traps in the film is in the range of 5×10¹⁰ to 1×10¹³ cm⁻² eV⁻¹.

According to a second aspect of the present invention, there is provided a silicon nitride film for use as a charge storage layer of a nonvolatile semiconductor memory device, wherein the volume density of traps in the film at an energy position corresponding to the mid-gap of silicon is distributed in the range of 1×10¹⁷ to 5×10¹⁷ cm⁻³ eV⁻¹ in the thickness direction of the film.

The silicon nitride film according to the present invention may contain oxygen.

According to a third aspect of the present invention, there is provided a silicon nitride film for use as a charge storage layer of a nonvolatile semiconductor memory device, wherein the film is formed by a plasma CVD method comprising: introducing a source gas containing a nitrogen-containing compound and a silicon-containing compound into a processing chamber of a plasma processing apparatus; introducing microwaves into the processing chamber by means of a plane antenna having a plurality of slots, thereby generating a plasma of the source gas; and depositing a silicon nitride film on a processing object in the plasma.

In the silicon nitride film of the third aspect of the present invention, it is preferred that the plasma CVD method use ammonia as the nitrogen-containing compound and disilane as the silicon-containing compound and be carried out at the flow rate ratio between the ammonia and the disilane (ammonia flow rate/disilane flow rate) in the range of 0.1 to 1000, at a processing pressure in the range of 1 to 1333 Pa and at a processing temperature in the range of 300 to 800° C.

The silicon nitride film according to the third aspect of the present invention may be formed by the plasma CVD method after forming a silicon dioxide film on the surface of the processing object.

In the silicon nitride film according to the third aspect of the present invention, the trap density of the film, in terms of the surface density, may be in the range of 5×10¹⁰ to 1×10¹³ cm⁻² eV⁻¹.

In the silicon nitride film according to the third aspect of the present invention, the trap density of the film, in terms of the volume density at an energy position corresponding to the mid-gap of silicon, may be distributed in the range of 1×10¹⁷ to 5×10¹⁷ cm⁻³ eV⁻¹ in the thickness direction of the film.

According to a fourth aspect of the present invention, there is provided a nonvolatile semiconductor memory device comprising a charge storage layer of a single-layer or multi-layer structure between a semiconductor layer and a gate electrode, wherein at least one layer of the charge storage layer is comprised of a silicon nitride film, and the trap density of the film, in terms of the surface density, is in the range of 5×10¹⁰ to 1×10¹³ cm⁻² eV⁻¹.

According to a fifth aspect of the present invention, there is provided a nonvolatile semiconductor memory device comprising a charge storage layer of a single-layer or multi-layer structure between a semiconductor layer and a gate electrode, wherein at least one layer of the charge storage layer is comprised of a silicon nitride film, and the trap density of the film, in terms of the volume density at an energy position corresponding to the mid-gap of silicon, is distributed in the range of 1×10¹⁷ to 5×10¹⁷ cm⁻³ eV⁻¹ in the thickness direction of the film.

The silicon nitride film according to the present invention has an excellent charge storage capacity. Accordingly, the present silicon nitride film, when used as a charge storage layer of a nonvolatile semiconductor memory device, can improve the data storage capacity of the nonvolatile semiconductor memory device.

### BRIEF DESCRIPTION OF THE DRAWINGS

FIG. 1 is a diagram schematically illustrating the construction of a nonvolatile semiconductor memory device using a silicon nitride film according to the present invention;

FIG. 2 is a schematic cross-sectional diagram illustrating an example of a plasma processing apparatus suited for forming a silicon nitride film according to the present invention;

FIG. 3 is a diagram illustrating the construction of a control section;

FIG. 4 is a graph showing the results of PYS measurement for silicon nitride films (thickness 3 nm);

FIG. 5 is a graph showing the results of PYS measurement for silicon nitride films (thickness 10 nm);

FIG. 6 is a graph showing the results of PYS measurement for a silicon nitride film and a hydrogen-terminated Si(100) surface;

FIG. 7 is a graph showing the depth direction distribution of the electron occupation defect density of a silicon nitride film;

FIG. 8 is a graph showing the results of XPS analysis of a silicon nitride film;

FIG. 9 is a graph showing the depth direction distributions of the electron occupation defect densities of the silicon nitride films of test categories I and J;

FIG. 10 is a graph showing the results of XPS analysis of the silicon nitride film of test category I; and

FIG. 11 is a graph showing the results of XPS analysis of the silicon nitride film of test category J.

### BEST MODE FOR CARRYING OUT THE INVENTION

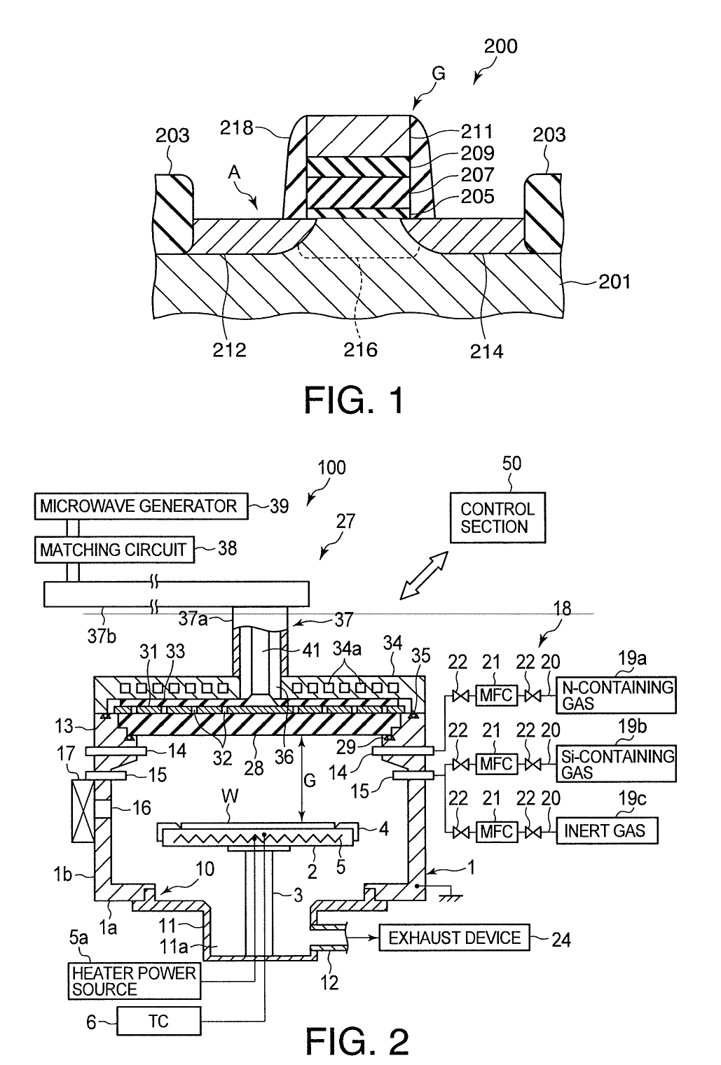

Preferred embodiments of the present invention will now be described with reference to the drawings. The following description illustrates, by way of example, an n channel-type nonvolatile semiconductor memory device using a silicon nitride film according to the present invention as a charge storage layer. FIG. 1 is a diagram illustrating the cross-sectional structure of a nonvolatile semiconductor memory device 200.

The nonvolatile semiconductor memory device 200 has a device structure S composed of a tunnel oxide film 205, a silicon nitride film 207, a silicon oxide film 209 and an electrode 211, formed in this order on e.g. a p-type silicon substrate (Si substrate) 201.

The tunnel oxide film 205 is, for example, an SiO₂ film or SiON film having a thickness of about 0.1 to 10 nm. The silicon nitride film 207 functions as a charge storage layer and is comprised, for example, of an SiN film or SiON film having a thickness of about 1 to 50 nm. As the silicon nitride film 207 is used a silicon nitride film according to the present invention, having an approximately uniform trap density distribution in the thickness direction of the film. It is also possible to provide two or more layers of silicon nitride films as a charge storage layer. The silicon oxide film 209 is an SiO₂ film formed, for example, by CVD (chemical vapor deposition) and functions as a block layer (barrier layer) between the electrode 211 and the silicon nitride film 207. The silicon oxide film 209 has a thickness of e.g. about 1 to 50 nm. The electrode 211 is comprised, for example, of a polycrystalline silicon film formed by CVD and functions as a control gate (CG) electrode. The electrode 211 may also be a film comprising a metal such as tungsten, titanium, tantalum, copper, aluminum or gold. The electrode 211 has a thickness of e.g. about 0.1 to 50 nm. The electrode 211 is not limited to a single-layer electrode but, for the purpose of lowering the resistivity of the electrode 211 and speeding up the device, may be of a laminate structure comprising, for example, tungsten, molybdenum, tantalum, titanium, a silicide or nitride thereof, or an alloy thereof, copper or aluminum. The electrode 211 is connected to a not-shown interconnect layer. The nonvolatile semiconductor memory device 200 may also be formed in a p well or a p-type silicon layer in a semiconductor substrate.

A device separation film 203 is formed in the surface of the Si substrate 201. An active region A in which the nonvolatile semiconductor memory device 200 is formed is defined by the device separation film 203. A source region 212 and a drain region 214 are formed around the device structure S in the Si substrate 201. The portion sandwiched between the source region 212 and the drain region 214 in the active region A is the channel region 216 of the nonvolatile semiconductor memory device 200. Side walls 218 are formed on both sides of the device structure S.

The operation of the nonvolatile semiconductor memory device 200 having the above structure will now be described. At the time of data writing, the source region 212 and the drain region 214 are held at 0 V with the electric potential of the Si substrate 201 as a reference, and a predetermined positive voltage is applied to the electrode 211. Then electrons are stored in the channel region 216 and an inversion layer is formed, and the electrons in the inversion layer partly move through the tunnel oxide film 205 to the silicon nitride film 207 by the tunnel effect. The electrons which have moved to the silicon nitride film 207 are captured in traps which are formed in the silicon nitride film 207 and serve as a charge capture center, whereby data is stored.

At the time of data reading, a voltage of 0 V is applied to one of the source region 212 and the drain region 214 with the electric potential of the Si substrate 201 as a reference, and a predetermined voltage is applied to the other. A predetermined voltage is applied also to the electrode 211. By the voltage application, the channel current and the drain voltage change depending on the presence or absence of electrons stored in the silicon nitride film 207 and the amount of stored electrons. Accordingly, stored data can be read out by detecting the change in the channel current or the drain voltage.

At the time of data erasing, a voltage of 0 V is applied to both the source region 212 and the drain region 214 with the electric potential of the Si substrate 201 as a reference, and a predetermined negative voltage is applied to the electrode 211. By the voltage application, electrons stored in the silicon nitride film 207 are drawn through the tunnel oxide film 205 into the channel region 216, whereby the nonvolatile semiconductor memory device 200 is returned to the erased state with a small amount of electrons stored in the silicon nitride film 207.

By using the silicon nitride film of the present invention, having an approximately uniform trap density distribution in the thickness direction of the film, as the silicon nitride film 207, the nonvolatile semiconductor memory device 200 can have an excellent data storage capacity. The silicon nitride film of the present invention can be used as a charge storage layer not only in an n channel-type nonvolatile semiconductor memory device as shown in FIG. 1, but in a p channel-type nonvolatile semiconductor memory device as well.

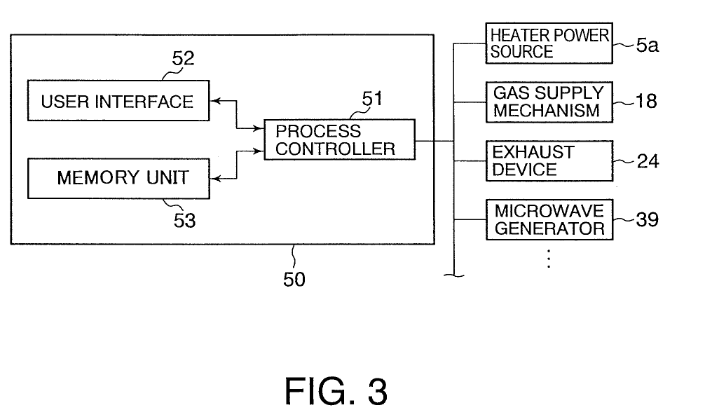

FIG. 2 is a cross-sectional diagram schematically illustrating the construction of a plasma processing apparatus 100 available for forming the silicon nitride film 207 in this embodiment. FIG. 3 is a diagram illustrating the construction of the control section of the plasma processing apparatus of FIG. 2.

The plasma processing apparatus 100 is constructed as an RLSA microwave plasma processing apparatus capable of generating a high-density, low-electron temperature, microwave-excited plasma by introducing microwaves into a processing chamber by means of an RLSA (radial line slot antenna), which is a plane antenna having a plurality of slot-like holes. The plasma processing apparatus 100 can perform processing with a plasma having a plasma density of 1×10¹⁰ to 5×10¹²/cm³ and a low electron temperature of 0.7 to 2 eV. The plasma processing apparatus 100 can therefore be advantageously used e.g. for the formation of a damage-free silicon nitride film by high-density plasma CVD in the manufacturing of a variety of semiconductor devices.

The plasma processing apparatus 100 mainly comprises an airtight chamber (processing chamber) 1, a gas supply mechanism 18 for supplying a gas into the chamber 1, an exhaust device 24 as an exhaust mechanism for evacuating and depressurizing the chamber 1, a microwave introduction mechanism 27, provided above the chamber 1, for introducing microwaves into the chamber 1, and a control section 50 for controlling these components of the plasma processing apparatus 100.

The chamber 1 is formed of a grounded, generally-cylindrical container. The chamber 1 may be formed of a container of a rectangular cylinder shape. The chamber 1 has a bottom wall 1a and a side wall 1b of e.g. aluminum.

In the chamber 1 is provided a worktable 2 for horizontally supporting a silicon wafer (hereinafter referred to simply as “wafer”) W as a processing object. The worktable 2 is made of a material having high thermal conductivity, for example, a ceramic material such as AlN. The worktable 2 is supported by a cylindrical support member 3 extending upwardly from the center of the bottom of an exhaust chamber 11. The support member 3 is made of a ceramic material such as AlN.

The worktable 2 is provided with a cover ring 4 for covering a peripheral portion of the worktable 2 and guiding the wafer W.

A resistance heating-type heater 5 as a temperature adjustment mechanism is embedded in the worktable 2. The heater 5, when powered from a heater power source 5a, heats the worktable 2 and, by the heat, uniformly heats the wafer W as a processing substrate.

The worktable 2 is also provided with a thermocouple (TC) 6. By carrying out temperature measurement with the thermocouple 6, the heating temperature of the wafer W can be controlled e.g. in the range of room temperature to 900° C.

The worktable 2 has wafer support pins (not shown) for raising and lowering the wafer W while supporting it. The wafer support pins are each projectable and retractable with respect to the surface of the worktable 2.

A circular opening 10 is formed generally centrally in the bottom wall 1a of the chamber 1. The bottom wall 1a is provided with a downwardly-projecting exhaust chamber 11 which communicates with the opening 10. An exhaust pipe 12 is connected to the exhaust chamber 11, and the exhaust chamber 11 is connected via the exhaust pipe 12 to the exhaust device 24.

Gas introduction sections 14 and 15 are provided in upper and lower two stages in the chamber 1. The gas introduction sections 14 and 15 are connected to the gas supply mechanism 18 which supplies film-forming source gases and a plasma-exciting gas. The gas introduction sections 14 and 15 may have the shape of a nozzle or a shower head.

The side wall 1b of the chamber 1 is provided with a transfer port 16 for transferring the wafer W between the plasma processing apparatus 100 and an adjacent transfer chamber (not shown), and a gate valve 17 for opening and closing the transfer port 16.

The gas supply mechanism 18 has, for example, a nitrogen-containing gas (N-containing gas) supply source 19a, a silicon-containing gas (Si-containing gas) supply source 19b and an inert gas supply source 19c. The nitrogen-containing gas supply source 19a is connected to the upper gas introduction section 14. The silicon-containing gas supply source 19b and the inert gas supply source 19c are connected to the lower gas introduction section 15. The gas supply mechanism 18 may also have a not-shown gas supply source(s) other than the above sources, for example, a purge gas supply source to be used for replacement of the atmosphere in the chamber, a cleaning gas supply source to be used for cleaning the interior of the chamber 1, etc.

Nitrogen gas (N₂), ammonia (NH₃), hydrazine derivatives such as MMH (monomethyl hydrazine), etc. can be used as a nitrogen-containing gas which is a film-forming source gas. Silane (SiH₄), disilane (Si₂H₆), TSA (trisilyl amine), etc. can be used as a silicon-containing gas which is the other film-forming source gas. Of these, disilane (Si₂H₆) is especially preferred. N₂ gas or a rare gas, for example, can be used as an inert gas. The rare gas is a plasma-exciting gas, and examples of usable rare gases include Ar gas, Kr gas, Xe gas and He gas.

A nitrogen-containing gas from the nitrogen-containing gas supply source 19a of the gas supply mechanism 18 passes through a gas line 20 and reaches the gas introduction section 14, and is introduced from the gas introduction section 14 into the chamber 1. On the other hand, a silicon-containing gas and an inert gas, respectively from the silicon-containing gas supply source 19b and the inert gas supply source 19c, each pass through a respective gas line 20 and reach the gas introduction section 15, and is introduced from the gas introduction section 15 into the chamber 1. The gas lines 20 connected to the respective gas supply sources are each provided with a mass flow controller 21 and on-off valves 22 located upstream and downstream of the controller 21. Such construction of the gas supply mechanism 18 enables switching of the gases supplied and control of the flow rate of each gas, etc. The plasma-exciting rare gas, such as Ar, is an optional gas and need not necessarily be supplied simultaneously with the film-forming source gases.

The exhaust device 24 as an exhaust mechanism includes a high-speed vacuum pump, such as a turbo-molecular pump. As described above, the exhaust device 24 is connected via the exhaust pipe 12 to the exhaust chamber 11 of the chamber 1. By the actuation of the exhaust device 24, the gas in the chamber 1 uniformly flows into the space 11a of the exhaust chamber 11, and is discharged from the space 11a through the exhaust pipe 12 to the outside. The chamber 1 can thus be quickly depressurized into a predetermined vacuum level, e.g. 0.133 Pa.

The construction of the microwave introduction mechanism 27 will now be described. The microwave introduction mechanism 27 mainly comprises a transmission plate 28, a plane antenna 31, a retardation member 33, a cover 34, a waveguide 37 and a microwave generator 39.

The transmission plate 28, which permits permeation therethrough of microwaves, is disposed on a support 13. The transmission plate 28 is composed of a dielectric material, for example, quartz. The interface between the transmission plate 28 and the support 13 is hermetically sealed with a seal member 29, so that the chamber 1 is kept hermetic.

The plane antenna 31 is provided over the transmission plate 28 such that it faces the worktable 2. The plane antenna 13 is locked into the upper end of the support 13.

The plane antenna 31 has a plurality of slot-like microwave radiating holes 32 that radiate microwaves. The microwave radiating holes 32, which penetrate the plane antenna 31, are formed in a predetermined pattern.

The retardation member 33, having a higher dielectric constant than vacuum, is provided on the upper surface of the plane antenna 31.

The cover 34, which is electrically conductive, is provided above the chamber 1 such that it covers the plane antenna 31 and the retardation member 33. The cover 34 is made of a metal material such as aluminum or stainless steel. The interface between the upper end of the support 13 and the cover 34 is sealed with a seal member 35. A cooling water flow passage 34a is formed in the interior of the cover 34. The cover 34, the retardation member 33, the plane antenna 31 and the transmission plate 28 can be cooled by passing cooling water through the cooling water flow passage 34a. The cover 34 is grounded.

An opening 36 is formed in the center of the upper wall (ceiling portion) of the cover 34, and the waveguide 37 is connected to the opening 36. The other end of the waveguide 37 is connected via a matching circuit 38 to the microwave generator 39 that generates microwaves.

The waveguide 37 is comprised of a coaxial waveguide 37a having a circular cross-section and extending upward from the opening 36 of the cover 34, and a rectangular waveguide 37b connected to the upper end of the coaxial waveguide 37a via a mode converter (not shown) that converts TE mode into TEM mode.

An inner conductor 41 extends centrally in the coaxial waveguide 37a. Microwaves are transmitted through the waveguide 37 to a flat waveguide, formed by the cover 34 and the plane antenna 31, radially, efficiently and uniformly.

With the microwave introduction mechanism 27 thus constructed, microwaves generated in the microwave generator 39 are transmitted through the waveguide 37 to the plane antenna 31, and introduced through the transmission plate 28 into the chamber 1. An exemplary microwave frequency which is preferably usable is 2.45 GHz. Other frequencies such as 8.35 GHz and 1.98 GHz can also be used.

The respective components of the plasma processing apparatus 100 are connected to and controlled by the control section 50. As shown in FIG. 3, the control section 50 includes a process controller 51 provided with a CPU, and a user interface 52 and a memory unit 53, both connected to the process controller 51. The process controller 51 is a control means which comprehensively controls those components of the plasma processing apparatus 100 which are related to process conditions, such as pressure, temperature, gas flow rate, etc. (heater power source 5a, gas supply mechanism 18, exhaust device 24, microwave generator 39, etc.)

The user interface 52 includes a keyboard for a process manager to perform a command input operation, etc. in order to manage the plasma processing apparatus 100, a display which visualizes and displays the operating situation of the plasma processing apparatus 100, etc. In the memory unit 53 are stored a control program (software) for executing under control of the process controller 51 various processings to be carried out in the plasma processing apparatus 100, and a recipe in which data on processing conditions, etc. is recorded.

A desired processing in the plasma processing apparatus 100 is carried out under the control of the process controller 51 by calling up an arbitrary recipe from the memory unit 53 and causing the process controller 51 to execute the recipe, e.g. through the operation of the user interface 52 performed as necessary. With reference to the process control program and the recipe of processing condition data, etc., it is possible to use those stored on a computer-readable storage medium, such as CD-ROM, hard disk, flexible disk, flash memory, blu-ray disc, etc. or to transmit them from another device e.g. via a dedicated line as needed, and use them online.

The plasma processing apparatus 100 thus constructed enables plasma CVD to be carried out at a low temperature of not more than 800° C. without damage to an underlying base film, etc. Further, the plasma processing apparatus 100, because of excellent plasma uniformity, can attain process uniformity.

In the RLSA plasma processing apparatus 100, the processing of depositing a silicon nitride film on the surface of a wafer W by plasma CVD is carried out by the following process. First, the gate valve 17 is opened, and a wafer W is carried from the transfer port 16 into the chamber 1 and placed on the worktable 2. Next, while evacuating and depressurizing the chamber 1, a nitrogen-containing gas and a silicon-containing gas are supplied from the nitrogen-containing gas supply source 19a and the silicon-containing gas supply source 19b of the gas supply mechanism 18 and introduced through the gas introduction sections 14, 15, respectively, into the chamber 1 respectively at a predetermined flow rate. In this manner the pressure in the chamber 1 is adjusted to a predetermined pressure.

Next, microwaves generated in the microwave generator 39, having a predetermined frequency, for example 2.45 GHz, are introduced via the matching circuit 38 into the waveguide 37. The microwaves introduced into the waveguide 37 pass through the rectangular waveguide 37b, the not-shown mode converter and the coaxial waveguide 37a, and are supplied through the inner conductor 41 to the plane antenna 31. The microwaves are then radiated from the slot-like microwave radiating holes 32 of the plane antenna 31 through the transmission plate 28 into the space above the wafer W in the chamber 1. The output power of the microwaves is preferably such as to make the power density per unit area (cm²) of the plane antenna 31 in the range of 0.41 W/cm² to 4.19 W/cm². An arbitrary microwave output power, which may vary depending on the size of the wafer W but provides a power density in the above range, can be selected e.g. from the range of 500 to 5000 W.

By the microwaves radiated from the plane antenna 31 into the chamber 1 via the transmission plate 28, an electromagnetic field is formed in the chamber 1, and the nitrogen-containing gas and the silicon-containing gas each turn into a plasma. Because the microwaves are radiated from the large number of microwave radiating holes 32 of the plane antenna 31, the microwave-excited plasma has a high density of about 1×10¹⁰ to 5×10¹²/cm³ and, in the vicinity of the wafer W, has a low electron temperature of not more than about 1.5 eV. The microwave-excited high-density plasma thus formed causes little damage to a base film. Dissociation of the source gases progresses in the high-density plasma and, by reaction of active species such as SiₚH_{q}, SiH_{q}, NH_{q}, N, etc. (p and q herein represent arbitrary numbers), a thin film of silicon nitride SiₓN_{y} or silicon oxynitride SiₓO_{z}N_{y} (x, y and z herein represent arbitrary numbers which are not necessarily determined stoichiometrically and vary depending on conditions) is deposited on the wafer W.

According to the present invention, the trap density of a silicon nitride film to be formed can be controlled at a desired value by selecting conditions in plasma CVD using the plasma processing apparatus 100. When forming a silicon nitride film e.g. having a high trap density (e.g. in the range of 5×10¹⁰ to 1×10¹³ cm⁻² eV⁻¹, preferably in the range of 1×10¹¹ to 1×10¹³ cm⁻² eV⁻¹, in terms of surface density), it is preferred to use NH₃ gas as a nitrogen-containing gas and Si₂H₆ gas as a silicon-containing gas. The flow rate ratio between NH₃ gas and Si₂H₆ gas (NH₃ gas flow rate/Si₂H₆ gas flow rate) is preferably in the range of 0.1 to 1000, more preferably in the range of 10 to 300. In particular, the NH₃ gas flow rate is set in the range of 10 to 5000 mL/min (sccm), preferably in the range of 100 to 1000 mL/min (sccm), and the Si₂H₆ gas flow rate is set in the range of 1 to 100 mL/min (sccm), preferably in the range of 5 to 20 mL/min (sccm) such that the above-described gas flow rate ratio is met. The processing pressure preferably is 1 to 1333 Pa, more preferably 50 to 650 Pa. Further, the power density of microwaves per unit area (cm²) of the plane antenna 31 is preferably made in the range of 0.41 to 4.19 W/cm². The use of the above conditions enables high-precision control of the amount of defects in the film formed.

In the above case, the plasma CVD processing temperature, i.e. the temperature of the worktable 2, is preferably not less than 300° C. and not more than 800° C., more preferably 400 to 600° C. The gap (between the lower surface of the transmission plate 28 and the upper surface of the worktable 2) G in the plasma processing apparatus 100 is preferably set e.g. at about 50 to 500 mm from the viewpoint of forming a silicon nitride film with a uniform thickness and good quality.

By carrying out plasma CVD under the above conditions by means of the plasma processing apparatus 100, a silicon nitride film having an approximately uniform trap density distribution in the thickness direction of the film can be formed. For example, in the silicon nitride film the volume density of traps at an energy position corresponding to the mid-gap of silicon is distributed in the range of 1×10¹⁷ to 5×10¹⁷ cm⁻³ eV⁻¹ in the thickness direction of the film and, from the interface with an underlying silicon layer to the surface of the film, the volume density of traps is distributed preferably in the range of 1×10¹⁷ to 2×10¹⁷ cm⁻³ eV⁻¹. Such a silicon nitride film has a high charge storage density. The thickness of the silicon nitride film may, for example, be 1 nm to 20 nm from a practical viewpoint. The volume density of traps, by raising it to the two-thirds power, can be converted into the surface density.

In the formation of a silicon nitride film by plasma CVD using the plasma processing apparatus 100, the trap density of the silicon nitride film can be increased by depositing the silicon nitride film on a silicon dioxide film (SiO₂ film). In this embodiment, therefore, it is preferred to form a thin SiO₂ film in the surface of a silicon base layer in advance when the silicon base layer is a silicon substrate composed of monocrystalline silicon or a polycrystalline silicon layer. In this case, the thin SiO₂ film may be any of a native oxide film, a thermally oxidized film and a plasma oxidized film. It is also possible to form a chemically oxidized film by chemically treating a Si surface with a chemical having oxidizing properties, such as HPM (hydrochloric acid-hydrogen peroxide-water mixture) or SPM (sulfuric acid-hydrogen peroxide-water mixture). The thickness of such a thin SiO₂ film, to be formed in the surface of a silicon base layer in advance, may preferably be 0.1 to 10 nm, more preferably 0.1 to 3 nm.

The trap density of a silicon nitride film formed by the silicon nitride film-forming method of this embodiment can be determined e.g. by utilizing PYS (photoemission yield spectroscopy) method. PYS is a method which involves irradiating a sample (silicon nitride film) with a light having a certain energy, and measuring the total energy of photoelectrons, emitted by photoelectric effect, as a function of the energy of the incident light. The PYS measurement can determine, with high sensitivity and in a nondestructive manner, the distribution of defect level density in a silicon nitride film and at the interface between the silicon nitride film and a silicon layer. In this regard, the photoelectron yield measured by PYS corresponds to the energy integral of the distribution of electron occupation density. Accordingly, the distribution of defect level density can be determined from derivative PYS spectra by the method of S. Miyazaki (Microelectron. Eng. 48 (1999) 63.).

A description will now be made of an experiment which was conducted to confirm the technical effects of the present invention. Using the plasma processing apparatus 100, various silicon nitride films were separately formed on a p-type silicon substrate (10 Ω·cm) under varying conditions. The resulting silicon nitride films were each measured by PYS. The PYS measurement was carried out by using an ultraviolet lamp, irradiating each silicon nitride film with ultraviolet light, and measuring emitted electrons with a photomultiplier. The experiment was conducted with respect to the test categories A to H shown in Table 1 below.

TABLE 1

| Test | Plasma CVD | Thickness of silicon | |
|---|---|---|---|
| category | conditions | nitride film | Pretreatment |
| Category A | Conditions 1 | 3 nm | DHF |
| | | | treatment |
| Category B | Conditions 1 | 3 nm | HPM |
| | | | treatment |
| Category C | Conditions 1 | 10 nm | DHF |
| | | | treatment |
| Category D | Conditions 1 | 10 nm | HPM |
| | | | treatment |
| Category E | Conditions 2 | 3 nm | DHF |
| | | | treatment |
| Category F | Conditions 2 | 3 nm | HPM |
| | | | treatment |
| Category G | Conditions 2 | 10 nm | DHF |
| | | | treatment |
| Category H | Conditions 2 | 10 nm | HPM |
| | | | treatment |

The details of the CVD plasma conditions shown in Table 1 are as follows:

### <Plasma CVD Conditions 1: N₂/Si₂H₆ Gas System>

N₂ gas flow rate: 1200 mL/min (sccm)
Si₂H₆ gas flow rate: 3 mL/min (sccm)
Flow rate ratio (N₂/Si₂H₆): 400
Processing pressure: 7.6 Pa
Temperature of worktable 2: 500° C.
Microwave power: 2000 W [power density is 1.67 W/cm² (per unit area (cm²) of plane antenna 31)]

### <Plasma CVD Conditions 2: NH₃/Si₂H₆ Gas System>

NH₃ gas flow rate: 800 mL/min (sccm)
Si₂H₆ gas flow rate: 10 mL/min (sccm)

Flow rate ratio (NH₃/Si₂H₆): 80

Processing pressure: 126 Pa
Temperature of worktable 2: 500° C.
Microwave power: 2000 W [power density is 1.67 W/cm² (per unit area (cm²) of plane antenna 31)]

The details of the pretreatments shown in FIG. 1 are as follows:

### <DHF Treatment>

Prior to plasma CVD film formation, the surface of the silicon substrate was treated with a 1% dilute hydrofluoric acid solution to remove a native oxide film.

### <HPM Treatment>

Prior to plasma CVD film formation, the surface of the silicon substrate was first treated with a 1% dilute hydrofluoric acid solution to remove a native oxide film, and then treated with 10% HPM (hydrochloric acid-hydrogen peroxide-water mixture) to form a SiO₂ film, which is a chemically oxidized film, on the surface of the silicon substrate.

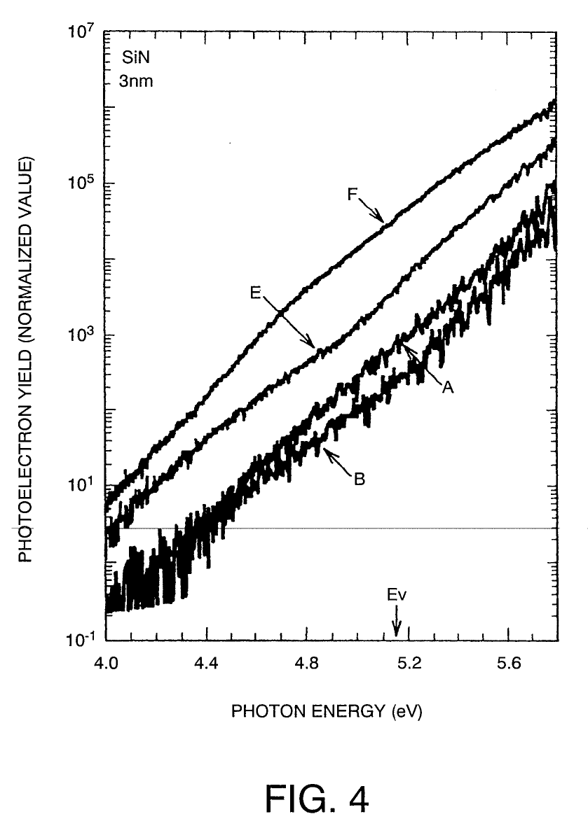

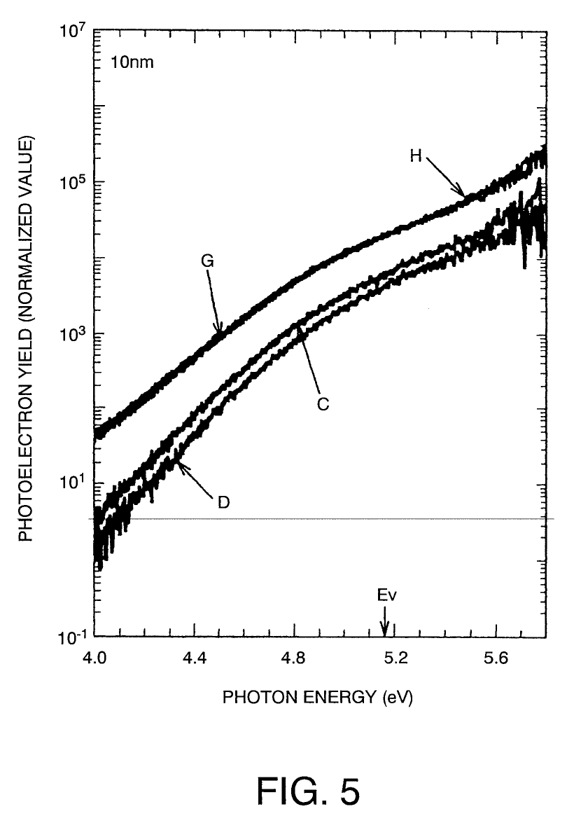

FIGS. 4 and 5 show the results of the PYS measurement. FIG. 4 shows the results for the silicon nitride films having a thickness of 3 nm, and FIG. 5 shows the results for the silicon nitride films having a thickness of 10 nm. Compared to the silicon nitride films formed under the plasma CVD conditions 1 using nitrogen and disilane as source gases and a processing pressure of 7.6 Pa (test categories A, B, C, D), the silicon nitride films formed under the plasma CVD conditions 2 using ammonia and disilane as source gases and a processing pressure of 126 Pa (test categories E, F, G, H) show a higher photoelectron yield, indicating a higher trap density.

The difference in the density of defect level due to the difference in the plasma CVD conditions is marked in the silicon nitride films having a thickness of 3 nm (test categories A, B, E, F) as compared to the silicon nitride films having a thickness of 10 nm (test categories C, D, G, H). Further, comparison of the data in FIG. 4 between categories E and F which both form the 3 nm-thick silicon nitride films under the same plasma CVD conditions, suggests that a silicon nitride film having a larger defect level density can be obtained by carrying out an HPM pretreatment to form a chemically oxidized SiO₂ layer on the surface of a silicon substrate in advance.

In another experiment, a chemical composition distribution and a defect level density distribution were determined and their correlation was examined for a silicon nitride film formed by plasma CVD using the plasma processing apparatus 100. A chemically oxidized SiO₂ layer was formed by the HTP treatment on the Si(100) surface of a p-type silicon substrate (10 Ω·cm) which had been subjected to the DHF treatment, and then a 11.4 nm-thick silicon nitride film was formed at a temperature of 400° C. The plasma CVD conditions are as follows: <Plasma CVD conditions 3: NH₃/Si₂H₆ gas system>

NH₃ gas flow rate: 800 mL/min (sccm)
Si₂H₆ gas flow rate: 16 mL/min (sccm)
Flow rate ratio (NH₃/Si₂H₆): 50
Processing pressure: 126 Pa
Temperature of worktable 2: 400° C.
Microwave power: 2000 W [power density is 1.67 W/cm² (per unit area (cm²) of plane antenna 31)]

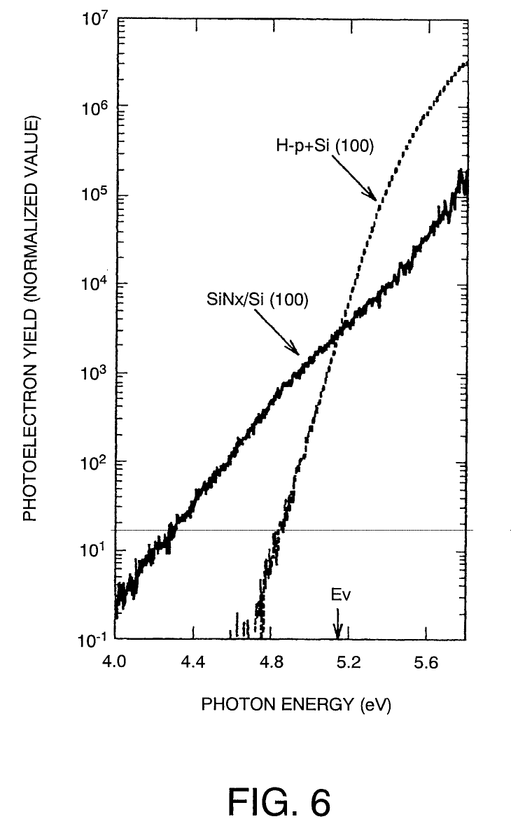

The silicon nitride film formed was etched with dilute hydrofluoric acid to make the film thinner, and PYS measurement and X-ray photoemission spectroscopy (XPS) measurement were carried out in the course of etching. FIG. 6 shows the results of PYS measurement for the prepared silicon nitride film [SiNₓ/Si(100)] and the hydrogen-terminated Si(100)[H−p+Si(100)] surface after 60-second etching. The data in FIG. 6 indicates that because of the presence of electron occupation defects (traps) in an energy region corresponding to the Si band gap in the silicon nitride film [SiNₓ/Si(100)], the photoelectron yield from the silicon nitride film is significantly higher as compared to the hydrogen-terminated Si(100)surface in a lower energy region (<5.15 eV) than the upper end (Ev) of the Si valence band.

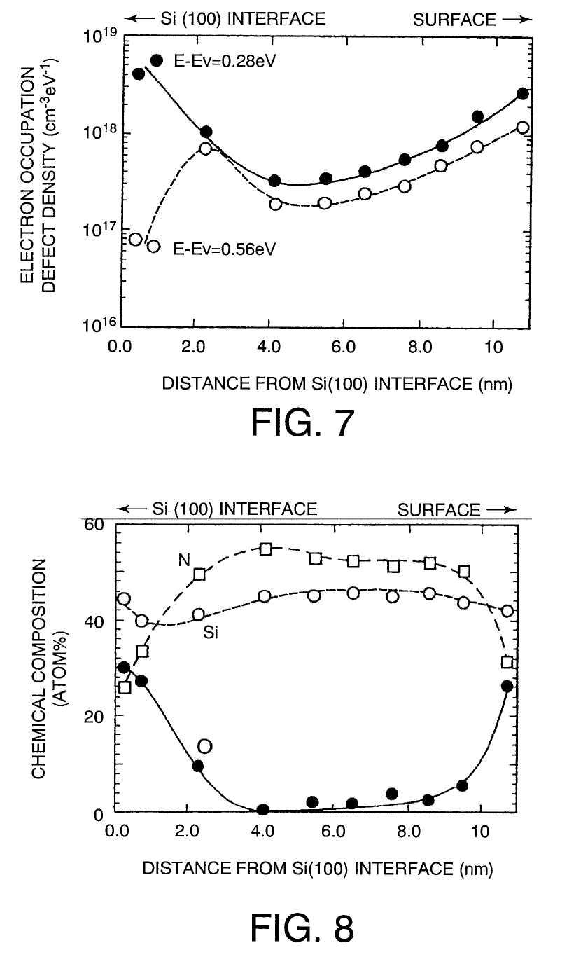

FIG. 7 shows the depth direction distribution of the electron occupation defect density, estimated from the change in the photoelectron yield in the course of etching. As indicated in FIG. 7, the electron occupation defect density (trap density) at an energy position shallower by 0.28 eV than the upper end (Ev) of the Si valence band (E−Ev=0.28 eV), the electron occupation defect density is at a maximum (6.0×10¹⁸ cm⁻³ eV⁻¹) in the vicinity of the Si substrate interface and at a minimum (3.2×10¹⁷ cm⁻³ eV⁻¹) at a position of about 4 nm from the Si substrate interface. At an energy position corresponding to the mid-gap of silicon (E−Ev=0.56 eV), the electron occupation defect density significantly decreases in the vicinity of the Si substrate interface, while the distribution of the electron occupation defect density, which is similar to that of the valence band side, was obtained in the silicon nitride film.

FIG. 8 shows the chemical composition profile of the silicon nitride film, determined by XPS analysis. As can be seen from FIG. 8, appreciable diffusion and mixing of oxygen atoms into the silicon nitride film is observed in a region in the vicinity of the surface of the silicon nitride film and in a region within about 3 nm in the thickness direction from the Si substrate interface. The oxidation on the surface side is considered to be due to native oxidation, while the oxidation on the Si substrate interface side is considered to be due to interfacial reaction between the chemically oxidized SiO₂ layer and the silicon nitride film.

As can be seen from comparison of the data in FIG. 7 for the energy position corresponding to the mid-gap of silicon (E−Ev=0.56 eV) with the XPS-determined chemical composition profile of the silicon nitride film, shown in FIG. 8, the region from the Si substrate interface to about 2 nm in the thickness direction, in which the electron occupation defect increases locally, corresponds to the vicinity of the interface between the chemically oxidized SiO₂ layer and the silicon nitride film. The results obtained thus indicate that in the silicon nitride film formed under the plasma CVD conditions 3, using the plasma processing apparatus 100, the electron occupation defect density in the film significantly increases in that vicinity of the interface between the chemically oxidized SiO₂ layer and the silicon nitride film into which oxygen atoms are diffused and mixed.

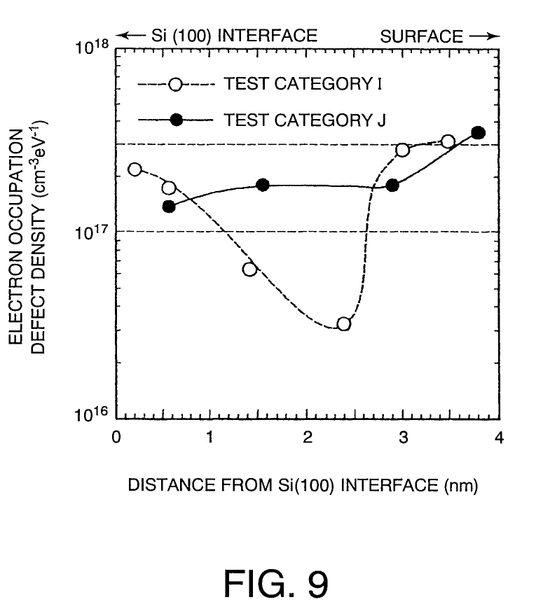

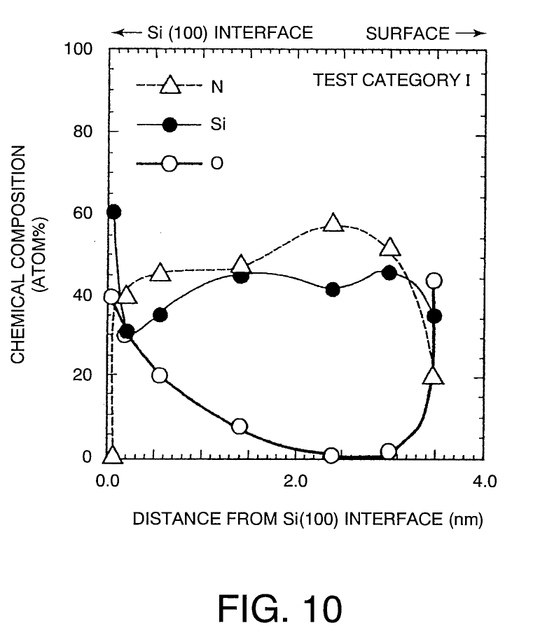

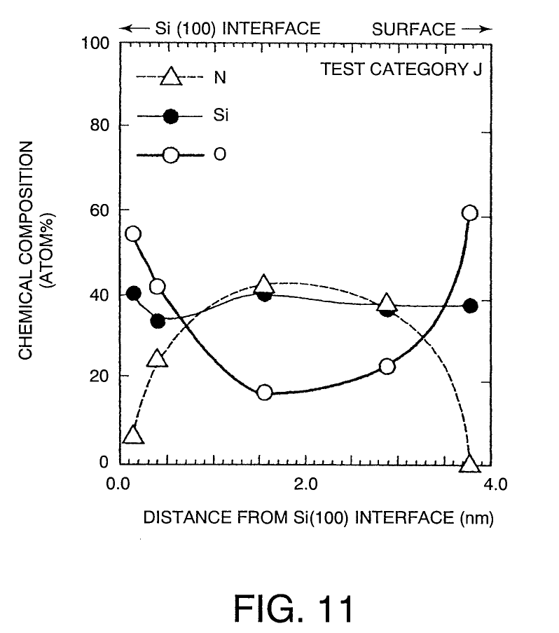

FIG. 9 shows the results of measurement of the depth direction distribution of electron occupation defect density at an energy position corresponding to the mid-gap of silicon, as determined for two types of silicon nitride films (test categories I and J) formed under different conditions, using the plasma processing apparatus 100. FIGS. 10 and 11 show the results of XPS measurement of the chemical composition profiles of the silicon nitride films of test categories I and J. The test category I (comparative example) relates to a 3.7 nm-thick silicon nitride film formed under the above-described plasma CVD conditions 1, while the category J relates to a 4.1 nm-thick silicon nitride film formed under the above-described plasma CVD conditions 2. In both the test categories I and J, plasma CVD was carried out after forming a 3 nm-thick chemically oxidized SiO₂ film by the HPM treatment.

As can be seen from FIG. 9, in the silicon nitride film of test category I (comparative example) formed under the plasma CVD conditions 1 using nitrogen and disilane, a region in which there is a significant decrease in electron occupation defect is present in the vicinity of the 2.5-nm distance position from the Si substrate interface. Thus, the silicon nitride film of test category I has a V-shaped profile of trap density: the electron occupation defect density is high in the vicinities of the interface and of the surface and low in the central portion. The silicon nitride film having such trap density profile entails a fear of easy escape of charges from the interface side and the surface side

On the other hand, in the case of the silicon nitride film of test category J, formed under the plasma CVD conditions 2 using ammonia and disilane as source gases, an approximately uniform distribution of electron occupation defect in the thickness direction of the film was confirmed. More specifically, in the silicon nitride film of test category J, the electron occupation defect density at an energy position corresponding to the mid-gap of silicon is approximately uniformly distributed in the range of 1×10¹⁷ to 5×10¹⁷ cm⁻³ eV⁻¹ in the thickness direction of the film. In the silicon nitride film of test category J, having such a uniform trap density in the thickness direction of the film, injected charges are held even in the central portion of the film. The silicon nitride film is therefore considered to less suffer from escape of charges and have a higher charge storage capacity as compared to the silicon nitride film of test category I (comparative example) in which many traps are present in the vicinities of the interface and the surface. The silicon nitride film of test category J can therefore be expected to exert the excellent charge storage capacity when used as a charge storage layer of a semiconductor memory device having a SONOS (MONOS) structure.

Further in regard to the silicon nitride film of test category J, as shown in FIG. 9, especially in the region of 1 nm to 3 nm from the Si substrate interface in the thickness direction, the electron occupation defect density at an energy position corresponding to the mid-gap of silicon is distributed in the narrow range of 1×10¹⁷ to 2×10¹⁷ cm⁻³ eV⁻¹. The silicon nitride film of test category J having such a very uniform trap density distribution, despite the small thickness, is considered to exert a sufficiently high charge storage capacity. Of course, a silicon nitride film according to the present invention can exert an excellent charge storage capacity when the film has a larger thickness; and a film having a thickness of 1 to 20 nm will be practically useful. The use of the silicon nitride film of the present invention can therefore fully meet the demand for finer, higher-capacity, highly-reliable semiconductor memory devices.

As can be seen from the chemical composition profile shown in FIG. 10, in the silicon nitride film of test category I (comparative example), the oxygen concentration in the film is high in the vicinity of the Si(100) interface and in the vicinity of the surface, whereas oxygen is little present around the center of the film. On the other hand, as can be seen from the chemical composition profile shown in FIG. 11, in the silicon nitride film of test category J, oxygen is present at a concentration of about 20 atom % even around the center of the film.

From comparison between the data of FIGS. 9 to 11 in terms of the distribution of oxygen in the respective silicon nitride film, it turns out that while the electron occupation defect density increases in those regions in which oxygen is present, the electron occupation defect density does not increase in proportion to an increase in the concentration of oxygen but plateaus even when oxygen is present e.g. at a concentration exceeding 20 atom %. It is therefore inferred that the production of electron occupation defects in a silicon nitride film is associated with dangling bonds produced in the silicon nitride film in the course of substitution reaction of trivalent nitrogen atom by divalent oxygen atom.

As described hereinabove, the silicon nitride film formed by plasma CVD using the plasma processing apparatus 100, carried out under the selected conditions, is the film in which the electron occupation defect density is controlled with high precision and which has a uniform trap density distribution in the thickness direction of the film. A silicon nitride film according to this embodiment can be used as an insulating film in the manufacturing of a variety of semiconductor devices and, especially when used as a charge storage layer of a nonvolatile semiconductor memory device, can meet the demand for excellent charge storage capacity, high reliability and higher capacity.

While the present invention has been described with reference to the embodiments thereof, the present invention is not limited to the embodiments, but various modifications may be made thereto. For example, though in the embodiments the silicon nitride film of the present invention is applied to the formation of a charge storage layer of a nonvolatile semiconductor memory device to enhance the charge storage capacity, it is applicable not only in the manufacturing of a nonvolatile semiconductor memory device but in the manufacturing of a variety of other semiconductor devices as well.

1. A silicon nitride film for use as a charge storage layer of a nonvolatile semiconductor memory device, wherein the surface density of traps in the film is in the range of 5×10¹⁰ to 1×10¹³ cm⁻² eV⁻¹.

2. A silicon nitride film for use as a charge storage layer of a nonvolatile semiconductor memory device, wherein the volume density of traps in the film at an energy position corresponding to the mid-gap of silicon is distributed in the range of 1×10¹⁷ to 5×10¹⁷ cm⁻³ eV⁻¹ in the thickness direction of the film.

3. A silicon nitride film for use as a charge storage layer of a nonvolatile semiconductor memory device, wherein the film is formed by a plasma CVD method comprising: introducing a source gas containing a nitrogen-containing compound and a silicon-containing compound into a processing chamber of a plasma processing apparatus; introducing microwaves into the processing chamber by means of a plane antenna having a plurality of slots, thereby generating a plasma of the source gas; and depositing a silicon nitride film on a processing object in the plasma.

4. The silicon nitride film according to claim 3, wherein the plasma CVD method uses ammonia as the nitrogen-containing compound and disilane as the silicon-containing compound and is carried out at the flow rate ratio between the ammonia and the disilane (ammonia flow rate/disilane flow rate) in the range of 0.1 to 1000, at a processing pressure in the range of 1 to 1333 Pa and at a processing temperature in the range of 300 to 800° C.

5. The silicon nitride film according to claim 3, wherein the film is formed by the plasma CVD method after forming a silicon dioxide film on the surface of the processing object.

6. The silicon nitride film according to claim 3, wherein the trap density of the film, in terms of the surface density, is in the range of 5×10¹⁰ to 1×10¹³ cm⁻² eV⁻¹.

7. The silicon nitride film according to claim 3, wherein the trap density of the film, in terms of the volume density at an energy position corresponding to the mid-gap of silicon, is distributed in the range of 1×10¹⁷ to 5×10¹⁷ cm⁻³ eV⁻¹ in the thickness direction of the film.

8. A nonvolatile semiconductor memory device comprising a charge storage layer of a single-layer or multi-layer structure between a semiconductor layer and a gate electrode, wherein at least one layer of the charge storage layer is comprised of a silicon nitride film, and the trap density of the film, in terms of the surface density, is in the range of 5×10¹⁰ to 1×10¹³ cm⁻² eV⁻¹.

9. A nonvolatile semiconductor memory device comprising a charge storage layer of a single-layer or multi-layer structure between a semiconductor layer and a gate electrode, wherein at least one layer of the charge storage layer is comprised of a silicon nitride film, and the trap density of the film, in terms of the volume density at an energy position corresponding to the mid-gap of silicon, is distributed in the range of 1×10¹⁷ to 5×10¹⁷ cm⁻³ eV⁻¹ in the thickness direction of the film.
